(19) United States
(12) Patent Application Publication
(10) Pub. No.: US 2025/0341022 A1
(43) Pub. Date: Nov. 6, 2025

(54) NANOCRYSTALLINE STRUCTURE SUBSTRATE

(71) Applicant: Tokushima University, Tokushima-shi Tokushima (JP)

(72) Inventors: Takaaki Yano, Tokushima-shi Tokushima (JP); Ryo Kato, Tokushima-shi Tokushima (JP)

(73) Assignee: Tokushima University, Tokushima-shi Tokushima (JP)

(21) Appl. No.: 19/267,400

(22) Filed: Jul. 11, 2025

Related U.S. Application Data
(63) Continuation of application No. PCT/JP2024/000439, filed on Jan. 11, 2024.

(30) Foreign Application Priority Data
Jan. 12, 2023 (JP) 2023-002784
Feb. 17, 2023 (JP) 2023-022990

(51) Int. Cl. C30B 29/06; C23C 14/20; C23C 14/24; C30B 28/02

(52) U.S. Cl. CPC C30B 29/06; C23C 14/20; C23C 14/24; C30B 28/02

(57) ABSTRACT

A nanocrystalline structure substrate includes a polymer layer provided on a surface of a base material, and nanocrystalline particles formed from a dielectric or semiconductor having a refractive index of 3 or more and an extinction coefficient of 3 or less at a wavelength of 500 nm or more and 800 nm or less fixed to a surface of the polymer layer.

### CROSS-REFERENCE TO RELATED APPLICATIONS

This application is a continuation application of International Application No. PCT/JP2024/000439, filed Jan. 11, 2024, which claims priority to Japanese Patent Application Nos. 2023-002784, filed Jan. 12, 2023, and 2023-022990, filed Feb. 17, 2023, each of which is incorporated herein by reference in its entirety.

### TECHNICAL FIELD

This disclosure relates to a nanocrystalline structure substrate that can be used for metamaterials or metasurfaces.

### BACKGROUND

Since ancient times, techniques have been used to color stained glass and glass crafts using metallic powders, utilizing a physical phenomenon in which nano-sized metallic particles exhibit plasmon resonance. In contrast, there has been recent research on Mie resonance produced in dielectric nanoparticles. Mie resonance is a phenomenon in which when light of wavelength λ is incident on dielectric nanoparticles of refractive index n and the effective wavelength (λ/n) is equal to the diameter of the dielectric nanoparticles, standing waves are generated in the particles, resulting in magnetic dipole resonance that is visible in the optical domain.

Silicon (Si), germanium (Ge), and gallium arsenide (GaAs), which have a high refractive index of 3 or higher, are preferred materials for dielectric nanoparticles (see Japanese Laid-open Patent Application Publication No. 2021-25023, Yano, “High Index Dielectric Nanophotonics of Refractive Nanoparticles,” Photonics News, Vol. 6, No. 3, 2020, and D. G. Baranov, D. A. Zuev, S. I. Lepeshov, O. V. Kotov, A. E. Krasnok, A. B. Evlyukhin, and B. N. Chichkov, “All-dielectric nanophotonics: the quest for better materials and fabrication techniques,” Optical Society of America, Vol. 4, No. 7, 2017). Further, dielectric nanoparticles with a smaller extinction coefficient are preferred, especially crystalline silicon with an extinction coefficient of 0.5 or less (see JP 2021-25023 A, Yano, “High Index Dielectric Nanophotonics of Refractive Nanoparticles,” Photonics News, Vol. 6, No. 3, 2020 and D. G. Baranov, D. A. Zuev, S. I. Lepeshov, O. V. Kotov, A. E. Krasnok, A. B. Evlyukhin, and B. N. Chichkov, “All-dielectric nanophotonics: the quest for better materials and fabrication techniques,” Optical Society of America, Vol. 4, No. 7, 2017).

Dielectric nanoparticles can arbitrarily change the wavelength of light absorption, or color, by controlling their material and particle size, and thus can be applied as ink materials. In principle, dielectric nanoparticles do not fade due to changes in molecular structure like organic dyes such as methylene blue. Therefore, dielectric nanoparticles are useful for signs that are permanently used in harsh conditions such as high temperatures or in the blazing sun. A common method for fixing dielectric nanoparticles on a substrate is to use electrostatic interaction between the dielectric nanoparticles and the substrate (see JP 2021-25023 A). For example, the surface of the substrate is pre-charged to a positive potential and the surface of the dielectric nanoparticles to a negative potential, and the solvent mixed with the dielectric nanoparticles is applied to the substrate and then fixed by evaporating the solvent.

Another method for fixing dielectric nanoparticles on substrates, besides laser ablation, is to use dewetting (see US Patent Application Publication No. 2017 0186612, Y. Wakayama, T. Tagami, and S. Tanaka, “Formation of Si islands from amorphous thin films upon thermal annealing,” J. Appl. Phys., Vol. 85, No. 12, 1999). For example, when a Si film is first vacuum deposited on a quartz glass crystal substrate and then the entire substrate is annealed to melt the Si film, the Si film is broken up into multiple islands, each of which agglomerates into a spherical shape due to surface tension. If slow cooling is carried out after that, a sphere of Si is crystallized.

However, when a nanocrystalline structure substrate is prepared using the technique disclosed in JP 2021-25023 A, the technique has a problem that the dielectric nanoparticles are merely attached to the substrate by electrostatic interaction and are easily peeled off by external forces. In addition, in the techniques in D. G. Baranov, D. A. Zuev, S. I. Lepeshov, O. V. Kotov, A. E. Krasnok, A. B. Evlyukhin, and B. N. Chichkov, “All-dielectric nanophotonics: the quest for better materials and fabrication techniques,” Optical Society of America, Vol. 4, No. 7, 2017 and Y. Wakayama, T. Tagami, and S. Tanaka, “Formation of Si islands from amorphous thin films upon thermal annealing,” J. Appl. Phys., Vol. 85, No. 12, 1999, the techniques have a problem that the entire substrate is heated to high temperatures, and thus, it is necessary to select a heat-resistant material such as quartz glass as the substrate, which limits the degree of freedom in material selection.

### SUMMARY

Disclosed herein is:

A nanocrystalline structure substrate including a polymer layer on the surface of a base material, and on the surface of the polymer layer are fixed nanocrystalline particles including a dielectric or semiconductor with a refractive index of 3 or higher and an extinction coefficient of 3 or lower at a wavelength of 500 nm or more and 800 nm or less.

In the nanocrystalline structure substrate, the polymer layer includes one or more thermoplastic polymers selected from the group consisting of polyethylene, polypropylene, styrene resin, vinyl chloride resin, methacrylic resin, polyethylene terephthalate (PET), polyamide, polyacrylonitrile polyethylene or one or more thermosetting resins selected from the group consisting of phenolic resin, polyurethane, epoxy resin, acrylic resin, and unsaturated polyester resin.

In the nanocrystalline structure substrate, the nanocrystalline particles are one or more single elements selected from the group consisting of Si, Ge, tellurium (Te), or one or more compounds selected from the group consisting of GaAs, gallium phosphorus (GaP), indium phosphorus (InP), titanium oxide (TiO₂), gallium antimonide (GaSb), lead telluride (PbTe), germanium telluride (GeTe), silicon carbide (SIC).

The nanocrystalline structure substrate may further have an amorphous layer on the surface of the polymer layer.

In some embodiments, the nanocrystalline structure substrate is one in which the surface of the nanocrystalline structure nanocrystalline particles is modified by fluorescent molecules.

In the nanocrystalline structure substrate, the fluorescent molecules are organic compounds selected from the group consisting of N-(3-Fluoranthyl) maleimide, FAM), fluorescein, dansyl, cascade yellow, fluoresceamine, Oregon green, pyrene, Texas Red, Pacific Blue, Marine Blue, Alexa, Lucifer Yellow, BODIPY, Coumarin, PyMPO, TET, JOE, Cy3, Cy5, Cy5.5, Cy7, ROX, VIC, HEX, T AMRA, SYBR Green, NBD.

In the nanocrystalline structure substrate, the thickness of the amorphous layer may be 10 nm or more and 100 nm or less.

It is possible to realize a nanocrystalline structure substrate in which nanocrystalline particles are stably provided on the substrate with the optical resonance wavelength controllable by the particle size.

According to some embodiments, a nanocrystalline structure substrate with a remarkable fluorescence enhancement effect can be achieved by modifying fluorescent molecules on the surface of nanocrystalline particles. In some embodiments, fluorescence intensity in any region can be controlled by leaving partially amorphous portions.

### BRIEF DESCRIPTION OF THE DRAWINGS

FIG. 1 is a schematic cross-sectional view of a nanocrystalline structure substrate of a first embodiment of this disclosure.

FIG. 2 is a schematic cross-sectional view of the nanocrystalline structure substrate of a second embodiment of this disclosure.

FIG. 3 is a schematic cross-sectional view of the nanocrystalline structure substrate of a third embodiment of this disclosure.

FIG. 4 illustrates the generation of nanocrystalline particles by laser annealing, and SEM images of the silicon nanoparticles produced.

FIGS. 5A and 5B each are a photograph of the dark-field microscope image in Example 1 of this disclosure.

FIGS. 6A to 6C show the results of fluorescence spectrum measurements in Example 2 and Comparative Examples of this disclosure.

FIGS. 7A to 7D each are a photograph of a dark-field microscope image of the coloration of each size of nanocrystalline particles in Example 3 of this disclosure.

### DETAILED DESCRIPTION

Features, advantages, and technical and industrial significance of exemplary embodiments of this disclosure will be described below with reference to the accompanying drawings, in which like numerals denote like elements.

### First Embodiment

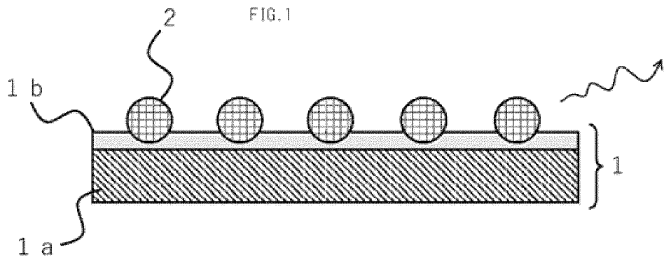

The first embodiment of this disclosure will be described in detail with reference to the drawings. FIG. 1 shows a schematic cross-sectional view of the nanocrystalline structure substrate. FIG. 1 shows a substrate 1 configured with a base material 1a and a polymer layer 1b formed on the surface of the base material 1a. The thickness of the base material 1a should be 100 μm or more from the viewpoint of strength. The material of the base material 1a is not limited and can be formed from any of metal, dielectric, semiconductor, resin, ceramic, or glass.

FIG. 1 shows nanocrystalline particles 2. The nanocrystalline particles 2 are configured with a dielectric or semiconductor that exhibits Mie resonance on its own. Mie resonance is a phenomenon in which, when light of wavelength λ is incident on an object of refractive index n, standing waves are formed when its effective wavelength λ/n is equal to the diameter of the particle, and electrical and magnetic dipole resonance appear in the optical domain. The larger refractive index indicates Mie resonance at smaller grain sizes. A high light confinement effect (light-enhancing effect) can be expected if the refractive index is about 4 or higher at a visible wavelength of 500 nm to 800 nm.

As for the material of nanocrystalline particles 2, a higher light confinement effect can be expected if the extinction coefficient k (the imaginary part of the refractive index), which is a factor in lowering the Q value of resonance, is smaller in conjunction with the above requirement of refractive index. The same effect can be expected with mono-elemental materials such as Si, Ge, and Te, or with compounds such as GaAs, GaP, InP, TiO₂, GaSb, PbTe, GeTe, SiC.

For example, the refractive index n of crystalline silicon (c-Si) is 4.293 to 3.486 at a wavelength of λ=500 nm to 1450 nm, so Mie resonance occurs with nanoparticles with a diameter of about a quarter of the wavelength in the visible light range (about 50 to 200 nm). Further, the extinction coefficient k of c-Si is about 0.0045-0.001 in the same wavelength range. In contrast, amorphous silicon (a-Si) is also almost equal to c-Si in refractive index. However, the extinction coefficient k deteriorates sharply at shorter wavelength ranges, reaching 1.12 at λ=500 nm, 250 times higher than that of c-Si.

Ge is a candidate as a semiconductor material other than silicon. Ge has a refractive index n in the mid wavelength range (λ=500 nm to 600 nm) of 4.035 to 5.748, slightly larger than c-Si. However, the extinction coefficient k is very large, ranging from 2.455 to 0.345 in the same wavelength range. In general, not only for a-Si and Ge, the shorter the wavelength, the worse the extinction coefficient k becomes. However, c-Si is one of the desirable materials for nanocrystalline particles since the degree of deterioration is slower than for other elements and compounds.

Further, in FIG. 1, a polymer layer 1b is provided between the base material 1a and the nanocrystalline particles 2. The material of choice is a polymer with a melting point temperature of 100° C. to 350° C. For example, thermoplastic polymers such as polyethylene, polypropylene, styrene resin, vinyl chloride resin, methacrylic resin, PET, nylon (polyamide), polyacrylonitrile polyethylene, thermosetting resins such as phenolic resin, polyurethane, epoxy resin, acrylic resin, unsaturated polyester resin, and other thermosetting resins.

### Second Embodiment

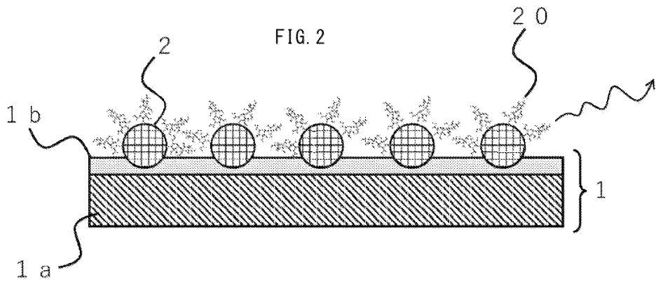

The second embodiment of this disclosure is described below. In the second embodiment, a case in which an application of the nanocrystalline structure substrate of the first embodiment to a fluorescent immunosensor is described. FIG. 2 is a schematic cross-sectional view of the nanocrystalline structure substrate in the second embodiment. In FIG. 2, the base material 1a, polymer layer 1b, and nanocrystalline particles 2 have functions equivalent to those shown in FIG. 1. The difference from FIG. 1 is that the surface of nanocrystalline particles 2 is modified with fluorescent probe molecules 20.

The fluorescent probe molecules 20 include, for example, N-(3-Fluoranthyl) maleimide, FAM), fluorescein, dansyl, cascade yellow, fluoresceamine, Oregon green, pyrene, Texas Red, Pacific Blue, Marine Blue, Alexa, Lucifer Yellow, BODIPY, Coumarin, PyMPO, TET, JOE, Cy3, Cy5, Cy5.5, Cy7, ROX, VIC, HEX, TAMRA, SYBRGreen, NBD, and others.

The nanocrystalline particles 2 are configured with semiconductor crystals, such as Si. Unlike metal nanoparticles, Si is less prone to surface-to-surface electronic transitions with fluorescent probe molecules. That is, there is no need to coat the surface with a polymer since the fluorescence intensity is not attenuated by the proximity of the fluorescent probe molecules to the surface. Therefore, the fluorescent probe molecules 20 may come into contact with the nanocrystalline particles 2, which can result in a significant fluorescence enhancement effect, as will be shown in the examples below.

### Third Embodiment

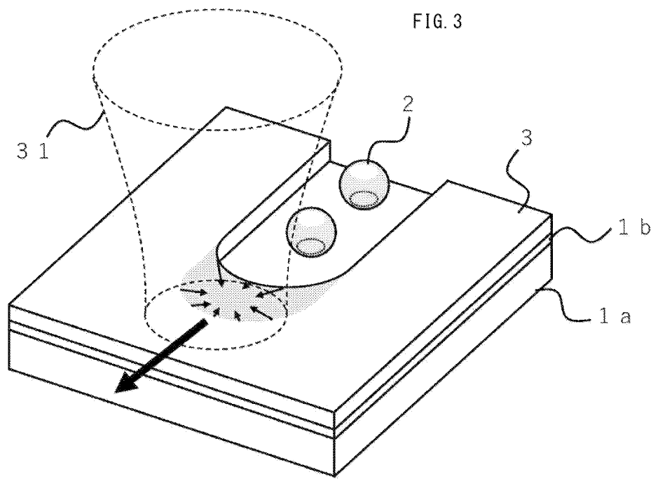

The third embodiment of this disclosure will be described below. FIG. 3 is a schematic perspective view of a nanocrystalline structure substrate in the third embodiment. In FIG. 3, the thickness of the amorphous layer 3 affects the size of the nanocrystalline particles that are finally generated, and is in some instances 10 nm or more and 100 nm or less. The composition of the amorphous layer may be a single element such as silicon (Si), germanium (Ge), or tellurium (Te), or a compound such as GaAs, GaP, InP, TiO2, GaSb, PbTe, GeTe, or SiC.

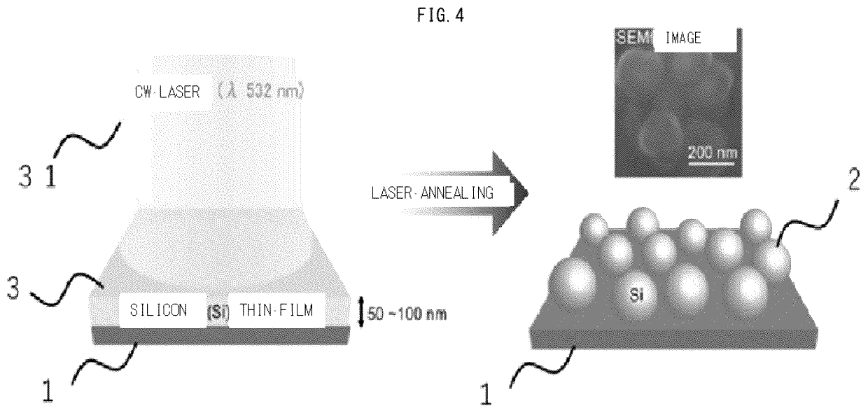

Next, the surface of the amorphous layer 3 is irradiated with laser light to partially heat and instantaneously melt the amorphous layer 3. The molten amorphous layer 3 (e.g., Si) is divided into a plurality of islands as shown in FIG. 4, aggregates into minute spheres, and solidifies to become crystalline silicon. Generally, the melting point of a-Si is approximately 1420° K. However, the thermal conductivity of the underlying polymer layer is approximately 0.1 to 0.5 W/m K, which is two to three orders of magnitude lower than that of Si (approximately 150 W/m K) or Ge (60 W/m K). As a result, the thermal energy supplied from the laser is almost entirely confined to the islands of the amorphous layer 3, and the nanocrystalline particles 2 can be generated by irradiating a low-energy laser.

Further, since the heating by the laser is limited to the area of the laser beam irradiated onto the surface of the amorphous layer 3, a much smaller input of energy is sufficient compared to the case where the entire substrate is annealed. The area of the laser beam, i.e., the size of the optical laser beam spot (e.g., the half-width), is generally determined by the wavelength of the laser and the numerical aperture of the objective optical system. However, the size of the temperature area where the amorphous layer 3 melts also depends on the power (irradiation energy) of the laser beam. In this embodiment, the laser beam irradiated onto the amorphous layer 3 is a line beam, and the beam diameter is 0.1 μm or more and 2.0 μm or less in length and 10 μm or more and 100 μm or less in width. The irradiation power is set to 1 mW or more and 10 mW or less. The wavelength of the laser may be selected so that the absorption rate by the amorphous layer 3 is as high as possible. However, in this embodiment, the wavelength is set to 488 nm or more and 630 nm or less.

In the case of generating nanocrystalline particles 2 over a wider area, for example, over the entire surface of the substrate, this can be achieved by scanning the surface while continuously irradiating the surface with a CW laser beam. That is, the amorphous layer 3 within the spot of the laser beam 31 melts once due to high heat, and then aggregates into an approximately spherical shape due to surface tension. Thereafter, when the laser beam spot passes, the temperature of the molten portion gradually decreases, and the molten portion crystallizes while maintaining the aggregated shape, forming nanocrystalline particles 2.

In this embodiment, the thickness of amorphous layer 3 also affects the size of the nanocrystalline particles that are ultimately generated. However, by changing the thickness of the amorphous layer 3 within the same substrate, it is possible to form nanocrystalline particles 2 that have different sizes, i.e., different Mie resonance wavelengths, depending on the location on the substrate. Changing the thickness of the amorphous layer 3 partially is achieved by initially forming the amorphous layer 3 to its maximum thickness, and then partially thinning the amorphous layer 3, for example, in a stepped manner, by fine grinding.

### EXAMPLES

Examples of this disclosure will now be described. In the following Examples, a glass substrate 1a having a thickness of 170 μm (C218181 manufactured by Matsunami Glass Ind., Ltd.) was used. A polymer layer 1b formed from ZEP-520A (polymer material) and having a thickness of 0.6 μm was provided on the surface. Further, a-Si having a thickness of 50 nm was formed on the surface of the polymer layer 1b using a vacuum deposition method, and the surface was scanned with a laser having a line beam diameter of 0.64 μm vertically and 20 μm horizontally, an irradiation power of 2 mW, and a wavelength of 532 nm to form nanocrystalline particles. Also shown as a comparative example is a sample in which a silicon crystal film, rather than nanocrystalline particles, is provided on a substrate.

### Example 1

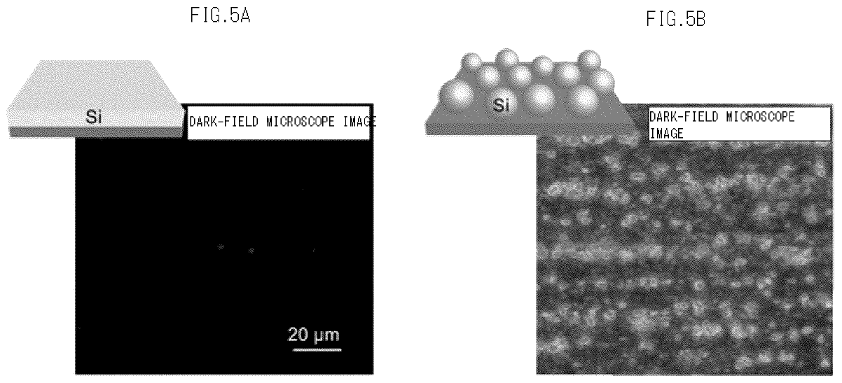

Photographs of dark field microscope images of the samples of Example 1 and the comparative example prepared as described above are shown in FIGS. 5A and 5B. As shown in FIG. 5B, in Example 1, strong optical resonance characteristics (Mie scattering resonance) were confirmed in the range from green (dim areas) to yellow-green (relatively bright areas), or in wavelengths of around 530 to 540 nm. In contrast, as shown in FIG. 5A, in the comparative example, the optical resonance phenomenon was not confirmed.

### Example 2

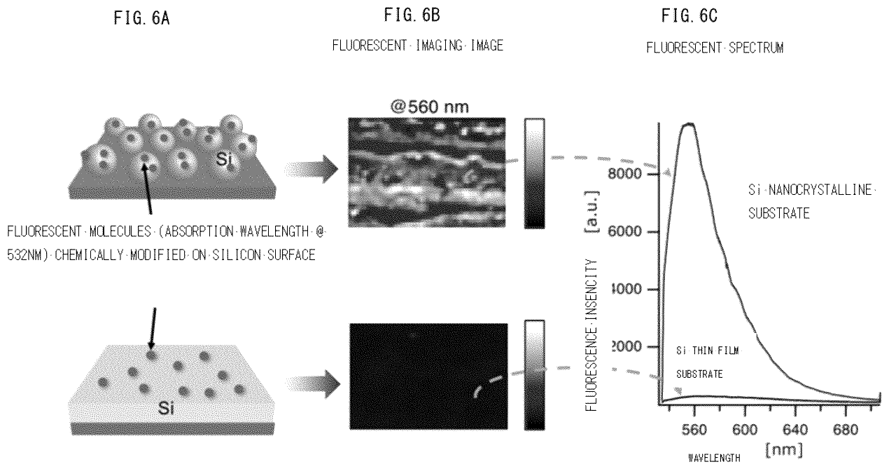

Further, the surface of the nanocrystalline particles was chemically modified with fluorescent molecules (AlexaFluor™ 532NHS Ester) and the fluorescence intensity was measured. The experimental results are shown in FIGS. 6A to 6C. A laser having a wavelength of 532 nm was irradiated onto each sample of the nanocrystalline structure substrate of Example 2 and a comparative example, and the fluorescence spectrum was measured. In the nanocrystalline structure substrate sample of Example 2, fluorescence was observed at 520 nm to 680 nm, with a peak at about 560 nm.

A fluorescence peak at a wavelength of about 560 nm can also be confirmed in the comparative example. However, the fluorescence peak is only a few percent higher than in the examples. In other words, it can be said that the nanocrystalline structure substrate of Example 2 enhances the fluorescence of the fluorescent molecules by nearly 100 times.

### Example 3

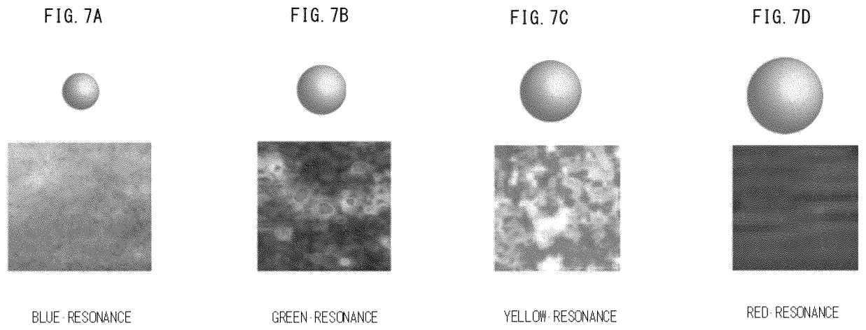

In Example 3, the relationship between the size of the nanocrystalline particles and the optical resonance wavelength was confirmed. FIGS. 7A to 7D are photographs of dark-field microscope images when the diameter of the nanocrystalline particles is changed to approximately 100 nm, 150 nm, 170 nm, and 200 nm, respectively.

It can be seen that the smaller the nanocrystalline particle, the bluer the color, and the larger the particle, the redder the color. It is therefore possible to distinguish between sizes according to the fluorescence wavelength. The nanoparticles shown in FIGS. 7A to 7D were produced by irradiating amorphous silicon layers having thicknesses of 30 nm, 50 nm, 70 nm, and 100 nm with a laser, respectively.

This disclosure can be used in biosensors for the diagnosis of emerging viral infectious diseases, which require urgent treatment, and for rapid clinical diagnosis at the bedside.

What is claimed is:

1. A nanocrystalline structure substrate comprising a polymer layer provided on a surface of a base material, and nanocrystalline particles formed from a dielectric or semiconductor having a refractive index of 3 or more and an extinction coefficient of 3 or less at a wavelength of 500 nm or more and 800 nm or less fixed to a surface of the polymer layer.

2. The nanocrystalline structure substrate according to claim 1, wherein the polymer layer contains one or more thermoplastic polymers selected from the group consisting of polyethylene, polypropylene, styrene-based resins, vinyl chloride resins, methacrylic resins, polyethylene terephthalate (PET), (polyamide), and polyacrylonitrile polyethylene, or one or more thermosetting resins selected from the group consisting of phenolic resins, polyurethanes, epoxy resins, acrylic resins, and unsaturated polyester resins.

3. The nanocrystalline structure substrate according to claim 1, wherein the nanocrystalline particles are one or more single elements selected from the group consisting of silicon, germanium, and tellurium, or one or more compounds selected from the group consisting of gallium arsenide, gallium phosphide, indium phosphide, titanium oxide, gallium antimonide, lead telluride, germanium telluride, and silicon carbide.

4. The nanocrystalline structure substrate according to claim 1, wherein an amorphous layer is further provided on the surface of the polymer layer.

5. The nanocrystalline structure substrate according to claim 4, wherein a thickness of the amorphous layer is 10 nm or more and 100 nm or less.

6. The nanocrystalline structure substrate according to claim 1, wherein the nanocrystalline particles have surfaces modified with fluorescent molecules.

7. The nanocrystalline structure substrate according to claim 6, wherein the fluorescent molecule is one or more organic compounds selected from the group consisting of N-(3-Fluoranthyl) maleimide, FAM), fluorescein, dansyl, cascade yellow, fluorescamine, Oregon green, pyrene, Texas red, Pacific blue, marine blue, Alexa, Lucifer yellow, BODIPY, coumarin, PyMPO, TET, JOE, Cy3, Cy5, Cy5.5, Cy7, ROX, VIC, HEX, TAMRA, SYBR Green, and NBD.
